(19) United States
(12) Patent Application Publication
(10) Pub. No.: US 2008/0083974 A1
(43) Pub. Date: Apr. 10, 2008

(54) Light-emitting device

(75) Inventor: Yuan-Cheng Chin, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/544,027

(22) Filed: Oct. 6, 2006

(51) Int. Cl. H01L 23/02

(52) U.S. Cl. 257/680

(57) ABSTRACT

A light-emitting device comprises: a coupling base, at least one light-emitting chip, a layer of glue, and a lens, wherein the coupling base is designed for coupling with at least one light-emitting chip. The light-emitting chip is electrically connected with a plurality of frames mounted inside the coupling base. The lens has a convex bottom. The glue is filled into the coupling base, and the lens is located on the glue, which is not yet dry. As a result, no bubble is formed on the contact junction between the lens and the glue after the glue is dry. Accordingly, the problems including poor refraction and poor transparency caused by the bubbles can be improved effectively.

### FIELD OF THE INVENTION

The present invention relates to a light-emitting device capable of improving poor refraction and non-uniform lighting.

### BACKGROUND OF THE INVENTION

The existing light-emitting diode is developed for the purpose of obtaining high brightness and low light loss so as to replace with the traditional lighting device. However, in addition to improving the structure of the light emitting diode, the refraction, the transparency, the uniformity, and the light-collecting ability of the glue that covers the outside of the light-emitting diode must be improved for the purpose of raising the brightness and reducing the light loss.

The conventional light-emitting diode has two frames, wherein a recessed cup is formed on one of these two frames for coupling with a chip. In addition, this chip is electrically connected with another frame via a conducting wire. Next, the chip, the conducting wire, and partial upper portions of these two frames are packaged by a layer of glue. There is disclosed a newer light-emitting diode that has a lens to further focus the light beams. As shown in FIG. 6, a chip A2 is attached to a frame A1, which is mounted inside a coupling base A, wherein the chip A2 is electrically connected to another frame A3, which is also mounted inside the coupling base A. In addition, a layer of glue B is filled into the coupling base A, and a lens C is further coupled with the top of the glue B so as to allow the light beams emitted from the chip A2 to pass through the lens C.

However, the above-mentioned lens C has a flat bottom, and the glue B has a concave or convex top surface because of surface tension or cohesion. As a result, the formation of bubble is inevitable when the lens C and the glue B are coupled with each other. The existence of bubble brings the light beams, which are emitted from the chip A2, the non-uniform refraction, transparency and lighting.

In view of the foregoing description, the present inventor makes diligent studies in providing consumers with a light-emitting device that has a lens to avoid the formation of bubble.

### SUMMARY OF THE INVENTION

It is a main object of the present invention to provide a light-emitting device that has a lens to avoid the formation of bubble and to uniform the lighting.

In order to achieve this object, a light-emitting device comprises: a coupling base, at least one light-emitting chip, a layer of glue, and a lens, wherein the coupling base is designed for coupling with at least one light-emitting chip. The light-emitting chip is electrically connected with a plurality of frames mounted inside the coupling base. The lens has a convex bottom. The glue is filled into the coupling base, and the lens is located on the glue, which is not yet dry. As a result, no bubble is formed on the contact junction between the lens and the glue after the glue is dry. Accordingly, the problems including poor refraction and poor transparency caused by the bubbles can be improved effectively.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational view showing a first preferred embodiment of the present invention.

FIG. 2 is a decomposed, cross-sectional view showing the first preferred embodiment of the present invention.

FIG. 3 is an assembled, cross-sectional view showing the first preferred embodiment of the present invention.

FIG. 4 is a top view showing the lens of the present invention.

FIG. 5 is an assembled, cross-sectional view showing a second preferred embodiment of the present invention.

FIG. 6 is an assembled, cross-sectional view showing a conventional light-emitting device.

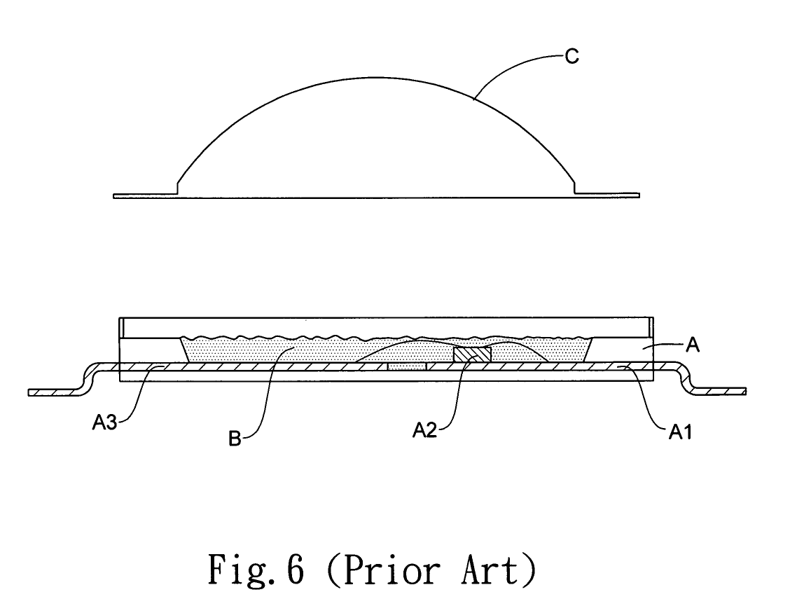

### DETAILED DESCRIPTION OF THE PREFERRED EMBODIMENT

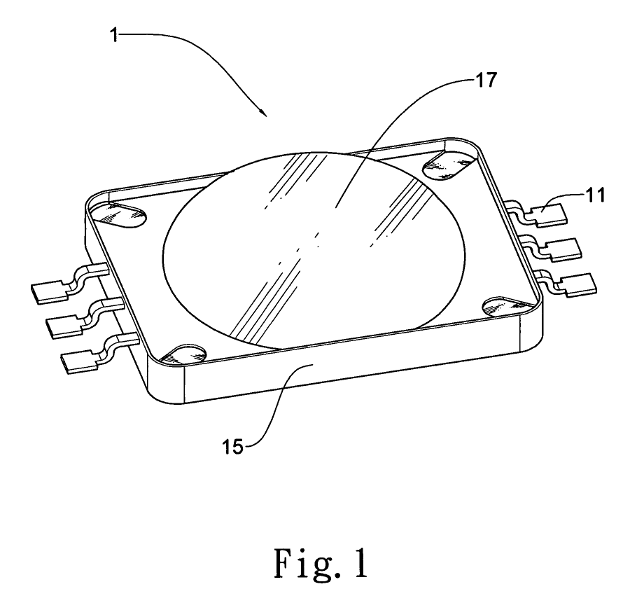

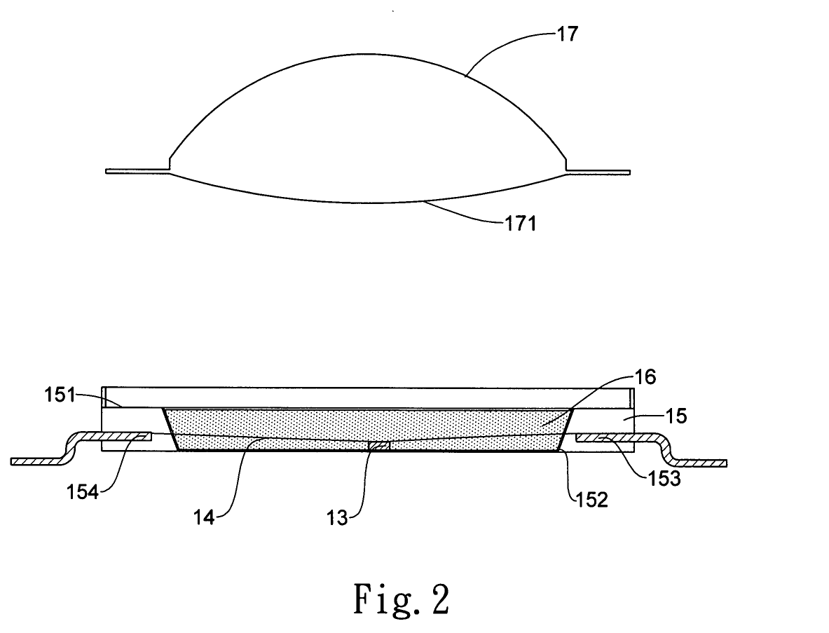

Referring to FIGS. 1 through 3, a light-emitting device 1 of the present invention comprises a coupling base 15, at least one chip 13, at least two bonding wires 14, a layer of glue 16, and a lens 17. The coupling base 15 has a recessed cup 152 and at least two frames 153 and 154 mounted therein. In addition, a ladder 151 is formed around the top of the coupling base 15. The chip 13 is attached to the inside of the recessed cup 152, and connected to the frames 153 and 154 via the bonding wires 14. The glue 16 is filled into the recessed cup 152 of the coupling base 15 so as to package the coupling base 15, the chip 13, and the bonding wires 14.

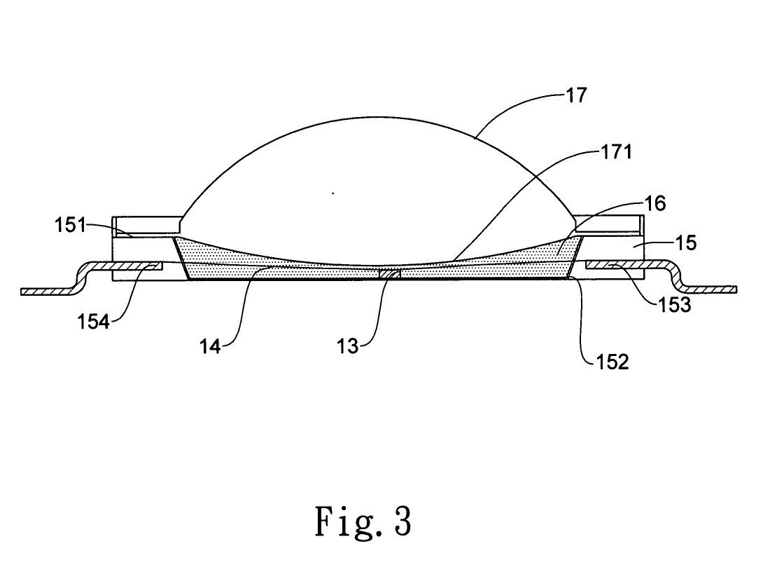

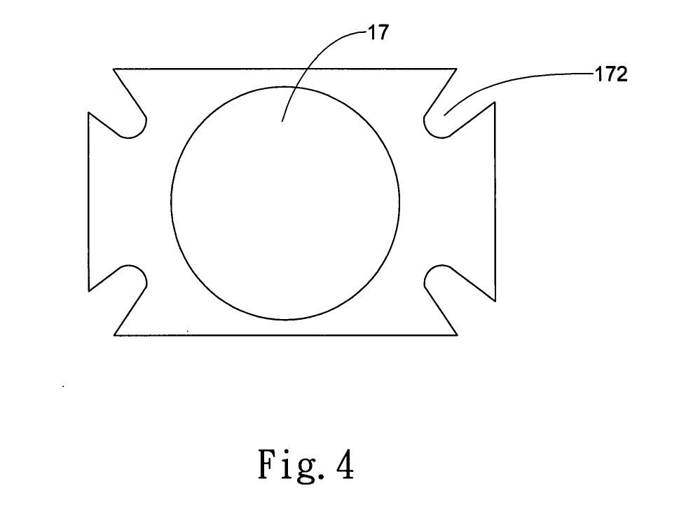

Referring to FIGS. 3 and 4, the lens 17 has a plate formed horizontally around its bottom to fit for the size of the coupling base 15. In addition, at least one notch is formed around the plate. In this preferred embodiment, a notch 172 is formed on each corner of the plate, and the lens 17 has a convex bottom 171.

In the assembly process, the recessed cup 152 of the coupling base 15 is filled with the glue 16. The convex bottom 171 of the lens 17 is placed downward to touch the top of the glue 16 by its center before the dryness of the glue 16. Next, the convex bottom 171 closely and gradually touches the glue 16 outwardly so that their contact surfaces can be flat and smooth and that the interior gas can be escaped from the notches 172 to avoid the formation of bubble. Moreover, the lens 17 is downward placed on the coupling base 15, and the plate of the lens 17 is held up by the ladder 151 of the coupling base 15. In addition, the glue 16, which is not yet dry, can be extruded by the convex bottom 171 of the lens 17 to flow into the notches 172 such that the lens 17 can be attached to the glue 16 closely.

The convex bottom 171 of the lens 17 has an arc surface, a spheric surface or an aspheric surface to allow the glue 16, which is not yet dry, to be attached to the convex bottom 171 smoothly.

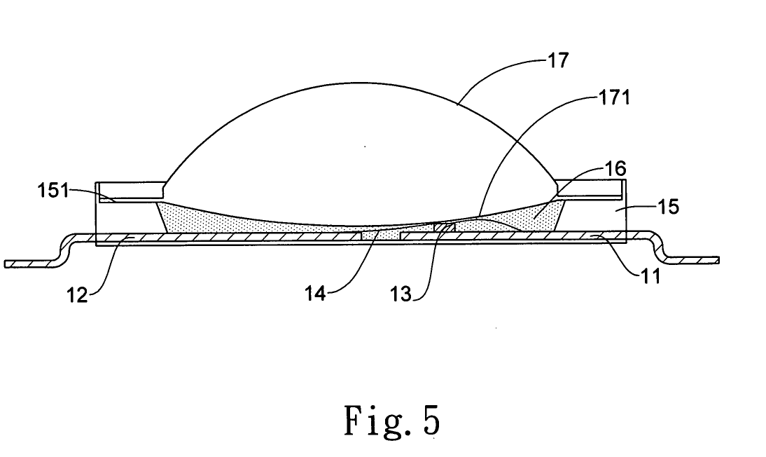

Referring to FIG. 5, the coupling base 15 may be composed of two frames 11 and 12. The chip 13 is coupled with the frame 11, and connected to the frames 11 and 12 via the bonding wires 14. The coupling base 15 is filled with the glue 16. The convex bottom 171 of the lens 17 is placed downward to touch the top of the glue 16 by its center before the dryness of the glue 16. Next, the convex bottom 171 gradually and closely touches the glue 16 outwardly so that their contact surfaces can be flat and smooth and the formation of bubble can be avoided.

From the above description, it can be seen that the present invention has the following advantages:

1. The lens has the convex bottom so that the gas can be excluded to the outside by attaching the center of the convex bottom with the top center of the glue so as to avoid the formation of bubble.

2. There are notches formed on four corners of the lens so that the glue, which is not yet dry, can be extruded by the lens to flow into the notches. Accordingly, the lens can be attached to the glue closely.

In summary, the light-emitting device of the present invention satisfies patentability and is thus submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-emitting device comprising:
a coupling base, at least one light-emitting chip, a layer of glue, and a lens, wherein said coupling base is designed for coupling with said at least one light-emitting chip, wherein said light-emitting chip is electrically connected with a plurality of frames mounted inside said coupling base, and said lens has a convex bottom, wherein said glue is filled into said coupling base, and said lens is located on said glue, which is not yet dry.

2. The light-emitting device of claim 1, wherein at least two frames are mounted in said coupling base.

3. The light-emitting device of claim 1, wherein at least two frames and a recessed cup are mounted in said coupling base.

4. The light-emitting device of claim 1, wherein said convex bottom has an arc surface.

5. The light-emitting device of claim 1, wherein said convex bottom has a spheric surface.

6. The light-emitting device of claim 1, wherein said convex bottom has an aspheric surface.

7. The light-emitting device of claim 1, wherein said lens has a plate formed horizontally around the bottom thereof.

8. The light-emitting device of claim 7, wherein at least one notch is formed around said plate.
